(19) United States
(12) Patent Application Publication
(10) Pub. No.: US 2009/0267160 A1
(43) Pub. Date: Oct. 29, 2009

(54) SEMICONDUCTOR DEVICE AND METHOD FOR MANUFACTURING THE SAME

(75) Inventor: Teruhisa ICHISE, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/428,036

(22) Filed: Apr. 22, 2009

(30) Foreign Application Priority Data
Apr. 28, 2008 (JP) 2008-117147

(51) Int. Cl. H01L 23/525; H01L 21/8238; H01L 27/092

(52) U.S. Cl. 257/369; 438/229; 257/E23.147; 438/199; 257/E27.062; 257/E21.632

(57) ABSTRACT

A semiconductor device comprises an anti-fuse element. The anti-fuse element includes a semiconductor substrate, a first gate insulating film, a first gate electrode, a high-concentration impurity region formed in the semiconductor substrate under the first gate electrode, and first source/drain regions provided in the semiconductor substrate on both sides of the high-concentration impurity region. The first source/drain regions contain an impurity having the same conduction type as conduction type of the high-concentration impurity region.

This application is based upon and claims the benefit of priority from Japanese Patent Application No. 2008-117147, filed on Apr. 28, 2008, the disclosure of which is incorporated herein in its entirety by reference.

### BACKGROUND OF THE INVENTION

1. Field of the Invention

The present invention relates to a semiconductor device and a method for manufacturing the semiconductor device.

2. Description of the Related Art

In a semiconductor device, to improve operational characteristic, to switch circuit functions, or for other purposes, it has been a typical practice to change circuit wiring information in the final manufacturing step to achieve a desired circuit operation.

An exemplary method for changing circuit wiring information involves providing a fuse in advance in a semiconductor device and externally inputting a specific signal to change the conduction state of the fuse for a desired circuit operation. The fuse used in this method is known as an anti-fuse (or also called an electric fuse), which is not conducting in the initial state and can be changed to be conducting in response to an external signal input.

Japanese Patent Laid-Open No. 2007-194486 discloses a technology for changing the conduction state of an anti-fuse formed in a semiconductor device including a MOS transistor, depending on the state of the gate insulating film of the MOS transistor, insulated or not.

A conventional anti-fuse element with a MOS transistor will be described with reference to the drawings. FIG. 1 is a longitudinal cross-sectional view of a conventional anti-fuse element. Gate electrode 52 is formed on semiconductor substrate 50 made of P-type silicon (Si) with interposed gate insulating film 51. Reference numerals 53 and 54 denote N-type diffusion layer regions (source/drain regions) formed by introducing impurity such as phosphorus to a high concentration.

A method for operating the conventional anti-fuse element will be described below. To determine the conduction state of the anti-fuse element, semiconductor substrate 50 and diffusion layer regions 53, 54 are set to the same fixed potential (ground potential, for example), and a low voltage at a level that does not break gate insulating film 51 is applied to gate electrode 52. The anti-fuse element is judged to be conducting when the gate current flowing in this state is monitored and the magnitude of the current is at least a preset reference current magnitude. In the initial state, the anti-fuse element is not conducting.

To change the conduction state, a high voltage is applied to gate electrode 52 to break gate insulating film 51 so that conduction paths are formed between gate electrode 52 and semiconductor substrate 50 or between gate electrode 52 and diffusion layer regions 53, 54. The conduction paths allow a gate current with a magnitude greater than or equal to the reference value to flow in the judgment operation described above. The anti-fuse element is thus judged to be conducting.

When a high voltage (+V) is applied to gate electrode 52 in the state shown in FIG. 1, the conduction paths formed through the broken gate insulating film conceivably terminate at any of the following three portions: semiconductor substrate 50, N-type diffusion layer region 53, and N-type diffusion layer region 54, from which the terminating portion is determined at random. The reason why the route of the conduction paths is determined at random is that the dielectric breakdown occurs at the weakest portion of the gate insulating film, which has been produced in the manufacturing steps, and the position of the weakest portion, in general, varies among a plurality of MOS transistors (including the anti-fuse element) formed in the semiconductor device.

### SUMMARY OF THE INVENTION

In one embodiment, there is provided a semiconductor device comprising an anti-fuse element, the anti-fuse element including:

a semiconductor substrate;

a first gate insulating film and a first gate electrode sequentially formed on the semiconductor substrate;

a high-concentration impurity region formed in the semiconductor substrate under the first gate electrode; and

first source/drain regions formed in the semiconductor substrate on both sides of the high-concentration impurity region, the first source/drain regions containing an impurity having the same conduction type as conduction type of the high-concentration impurity region.

In another embodiment, there is provided a method for manufacturing a semiconductor device including an anti-fuse element, the method comprising:

implanting an impurity into a predetermined area of a semiconductor substrate to form a high-concentration impurity region and first source/drain regions in the semiconductor substrate on both sides of the high-concentration impurity region; and

sequentially forming a first gate insulating film and a first gate electrode on the high-concentration impurity region to form the anti-fuse element.

In another embodiment, there is provided a method for manufacturing a semiconductor device including an anti-fuse element, the method comprising:

implanting a first impurity into a predetermined area of a semiconductor substrate;

sequentially forming a first gate insulating film and a first gate electrode on part of the predetermined area, to define the predetermined area under the first gate electrode as a high-concentration impurity region comprising the first impurity; and

implanting a second impurity having the same conduction type as conduction type of the first impurity into the predetermined area on both sides of the first gate electrode, to form first source/drain regions, and then obtain the anti-fuse element.

### BRIEF DESCRIPTION OF THE DRAWINGS

The above features and advantages of the present invention will be more apparent from the following description of certain preferred embodiments taken in conjunction with the accompanying drawings, in which:

FIG. 1 shows a related conductor device;

FIG. 2 shows a step of an exemplary method for manufacturing a semiconductor device of the present invention;

FIG. 3 shows a step of the exemplary method for manufacturing a semiconductor device of the present invention;

FIG. 4 shows a step of the exemplary method for manufacturing a semiconductor device of the present invention;

FIG. 5 shows a step of the exemplary method for manufacturing a semiconductor device of the present invention;

FIG. 6 shows a step of the exemplary method for manufacturing a semiconductor device of the present invention;

FIG. 7 shows a step of the exemplary method for manufacturing a semiconductor device of the present invention;

FIG. 8 shows a step of the exemplary method for manufacturing a semiconductor device of the present invention;

FIG. 9 shows a step of the exemplary method for manufacturing a semiconductor device of the present invention;

FIG. 10 shows a step of the exemplary method for manufacturing a semiconductor device of the present invention;

FIG. 11 shows a step of the exemplary method for manufacturing a semiconductor device of the present invention;

FIG. 12 shows a step of the exemplary method for manufacturing a semiconductor device of the present invention;

FIG. 13 shows a step of the exemplary method for manufacturing a semiconductor device of the present invention;

FIG. 14 shows a step of the exemplary method for manufacturing a semiconductor device of the present invention;

FIG. 15 shows a step of the exemplary method for manufacturing a semiconductor device of the present invention;

FIG. 16 shows a step of the exemplary method for manufacturing a semiconductor device of the present invention; and

FIG. 17 shows a step of the exemplary method for manufacturing a semiconductor device of the present invention.

In the drawings, numerals have the following meanings. 1: semiconductor substrate, 2: isolation region, 3: high-concentration impurity region, 4: gate insulating film, 5: conductive film, 6: gate electrode, 7: source/drain region, 8: interlayer insulating film, 9: contact plug, 10: metal wired line, 12: high melting point metal film, 13: silicon nitride film, 14: gate electrode, 15: sidewall, 25: film, 26: film, 30: photoresist film

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

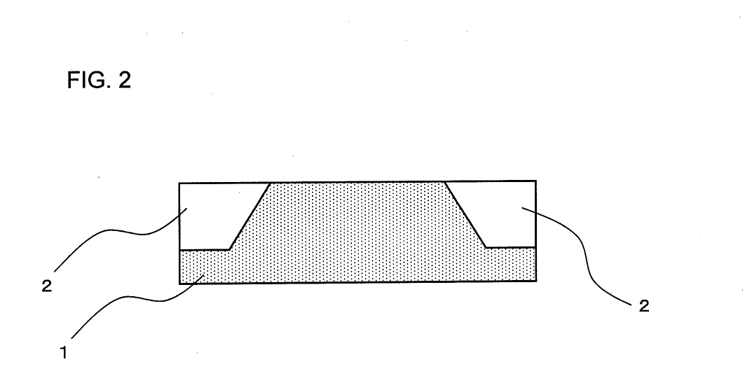

A method for manufacturing an anti-fuse element will be described with reference to the drawings. First, as shown in FIG. 2, a silicon oxide film (SiO₂) or any other suitable insulating film was embedded in accordance with STI (Shallow Trench Isolation) formation technology to form isolation region 2 in semiconductor substrate 1 made of P-type silicon. A P-type well may be formed in advance in semiconductor substrate 1, in which the anti-fuse element is to be formed, by introducing P-type impurity such as boron to a low concentration (approximately 1×10¹³ atoms/cm²) in an ion implantation process.

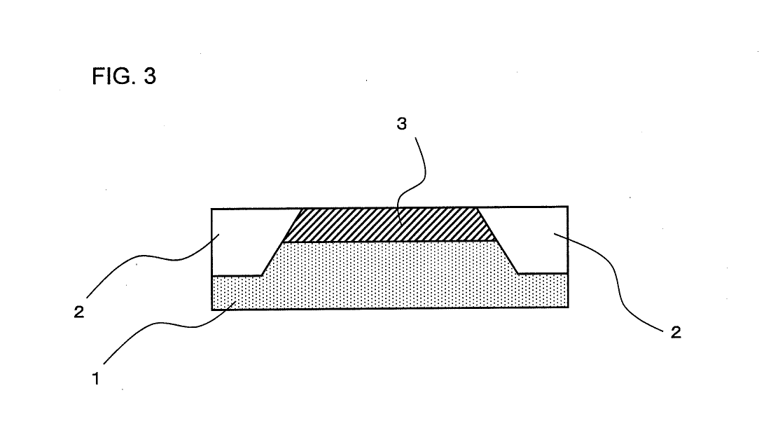

N-type impurity such as phosphorus and arsenic (corresponding to a first impurity) was then introduced to a high concentration in an ion implantation process to form N-type high-concentration impurity region 3 in semiconductor substrate 1, as shown in FIG. 3. The ion implantation may be specifically carried out under the following conditions: the implantation energy ranges from 10 to 30 KeV, and the dosage ranges from approximately 1×10¹⁴ to 1×10¹⁶ atoms/cm². It is noted that the N-type impurity introduced into isolation region 2 is not shown in the drawings because the impurity in this region has nothing to do with the operation of the anti-fuse element.

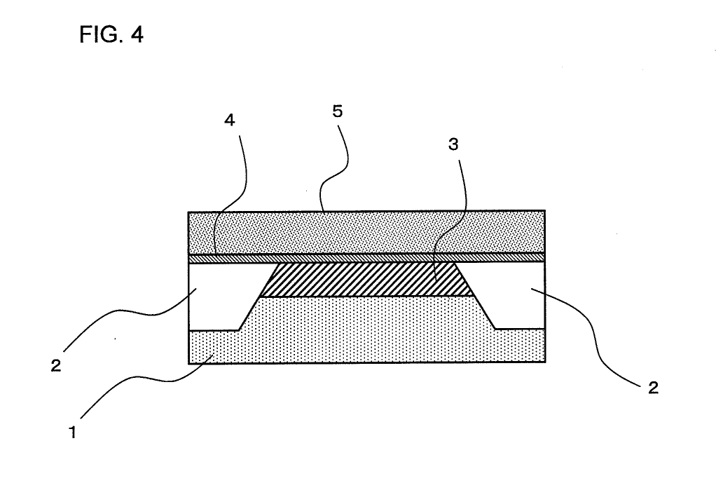

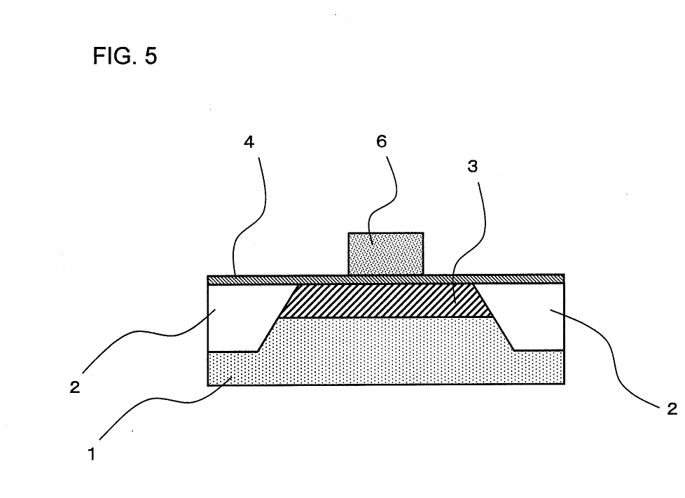

On semiconductor substrate 1 were then formed first gate insulating film 4 comprised of a silicon oxide film and conductive film 5 made of impurity-introduced polycrystalline silicon (Poly-Si), as shown in FIG. 4. Thereafter, conductive film 5 was patterned by using known photolithography and dry etching technologies to form first gate electrode 6, as shown in FIG. 5.

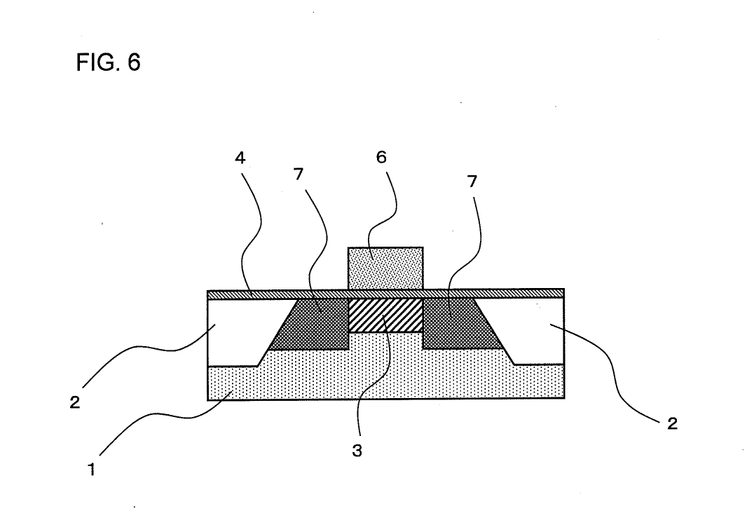

N-type impurity such as phosphorus and arsenic (corresponding to a second impurity) was then ion-implanted by using first gate electrode 6 as a mask to form first source/drain regions 7, as shown in FIG. 6. The ion implantation may be specifically carried out under the following conditions: the implantation energy ranges from 10 to 30 KeV, and the dosage ranges from approximately 1×10¹⁴ to 1×10¹⁶ atoms/cm². The ion implantation conditions in the formation of first source/drain regions 7 may differ from those in the formation of high-concentration impurity region 3, but the ion species to be implanted into high-concentration impurity region 3 and first source/drain regions 7 should be the same.

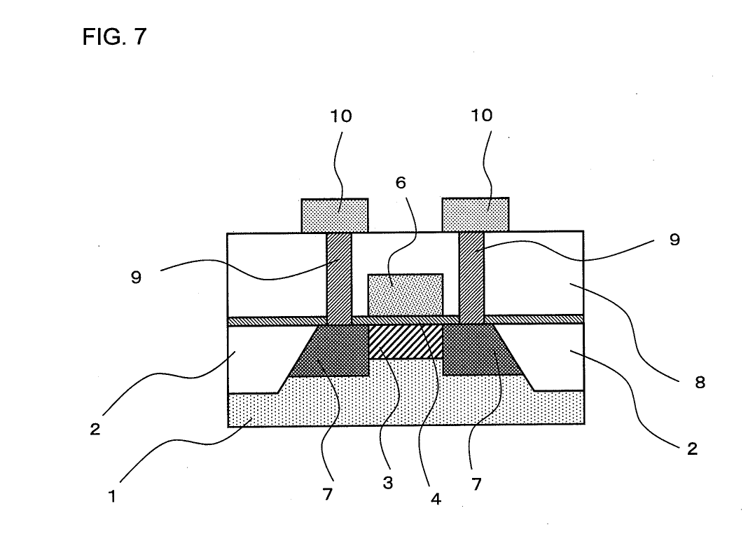

Interlayer insulating film 8 comprised of, for example, a silicon oxide film was then formed to cover first gate electrode 6, as shown in FIG. 7. Thereafter, tungsten (W) or any other suitable material was used to form contact plugs 9 for connection with the first source/drain regions, a contact plug (not shown) for connection with the first gate electrode, and electrode-extending metal wired lines 10. A surface protecting insulating film is then formed, and an overlying metal wired line layer and other components were further formed as required. The anti-fuse element was thus completed.

The operation of the anti-fuse element will be described below. To determine the conduction state of the anti-fuse element, in FIG. 7, semiconductor substrate 1 and first source/drain regions 7 are set to the same fixed potential (ground potential, for example), and a low voltage at a level that does not break first gate insulating film 4 is applied to first gate electrode 6. The gate current flowing in this state is monitored and compared with a preset reference current magnitude. When the current magnitude is greater than or equal to the reference current magnitude, the anti-fuse element is judged to be conducting. In the initial state, the anti-fuse element is not conducting. The conduction state of the anti-fuse element can therefore be judged correctly.

To change the conduction state of the anti-fuse element, semiconductor substrate 1 and first source/drain regions 7 are set to the same fixed potential, and then a high voltage is applied to first gate electrode 6 to form conduction paths due to dielectric breakdown. The conduction paths formed due to the dielectric breakdown of the first gate insulating film terminate at either first source/drain regions 7 or high-concentration impurity region 3. In either case, the connection resistance of the conduction paths can be kept low, because the N-type impurity has been introduced to a high concentration in semiconductor substrate 1. Further, since first source/drain regions 7 and high-concentration impurity region 3 have low wiring resistance, increase in electric resistance can be suppressed at the time of gate current judgment irrespective of the location of the formed conduction paths.

While the above exemplary embodiment has been described with reference to the case where N-type high-concentration impurity region 3 and N-type first source/drain regions 7 are formed in P-type semiconductor substrate 1, the conduction types can be changed. In this case, a low-concentration N-type well may be formed in advance in the area of the semiconductor substrate where an anti-fuse element is to be formed, and impurity such as boron and boron fluoride (BF₂) may be ion-implanted to a high concentration to form a P-type diffusion layer region, which will serve as high-concentration impurity region 3 and first source/drain regions 7. When a P-type high-concentration impurity region is formed as well, the ion implantation can be carried out under the following conditions: the implantation energy ranges from 10 to 30 KeV, and the dosage ranges from approximately 1×10¹⁴ to 1×10¹⁶ atoms/cm².

The method described above for applying a voltage to operate the anti-fuse element is presented by way of example and is not the only way. For example, semiconductor substrate 1 and first source/drain regions 7 may be set to have the same negative potential (a value ranging from approximately −1 to −2 V). Further, the potential applied to first source/drain regions 7 may differ from that applied to semiconductor substrate 1.

The material used for forming the anti-fuse element can be changed as long as the anti-fuse element material does not depart from the scope of the present invention. For example, the first gate electrode is not necessarily comprised of a polycrystalline silicon single layer film. The first gate electrode may be a multilayer film obtained by stacking a polycrystalline silicon film and a high melting point metal film such as tungsten, or a single layer film made of a high melting point metal. In this case, a silicide film can be formed. The silicide film can be formed, for example, by sequentially forming a polysilicon film and a metal film followed by heat treatment for silicidation. The type of the metal is not limited to a specific one as long as the metal reacts with silicon to form a silicide. Examples of such a metal may include Ni, Cr, Ir, Rh, Ti, Zr, Hf, V, Ta, Nb, Mo, and W. Examples of the silicide may include NiSi, Ni₂Si, Ni₃Si, NiSi₂, WSi₂, TiSi₂, VSi₂, CrSi₂, ZrSi₂, NbSi₂, MoSi₂, TaSi₂, CoSi, CoSi₂, PtSi, Pt₂Si, and Pd₂Si.

The first gate insulating film can alternatively be made of a material other than a silicon oxide or comprised of a laminate made of a plurality of materials. Specific examples may include a silicon oxide film (SiO₂), a silicon nitride film (Si₃N₄), a silicon oxynitride film, a laminate of the above-mentioned films, and an oxide film containing hafnium (Hf). Another example of the first gate insulating film may be a high-K insulating film made of a metal oxide, a metal silicate, or a metal-oxide- or metal-silicate-based material to which nitrogen is introduced.

The “high-K insulating film” used herein refers to an insulating film having a dielectric constant higher than that of SiO₂ (approximately 3.6 for SiO₂), which has been widely used as the first gate insulating film in a semiconductor device. The dielectric constant of a high-K insulating film can typically range from tens to thousands. Examples of such a high-K insulating film may include HfSiO, HfSiON, HfZrSiO, HfZrSiON, ZrSiO, ZrSiON, HfAlO, HfAlON, HfZrAlO, HfZrAlON, ZrAlO, and ZrAlON.

In the above description of the anti-fuse element of the present invention, the portions having the same configurations as those of the gate insulating film, the gate electrode, and the source/drain regions that form a typical MOS transistor are named “gate insulating film,” “gate electrode,” and “source/drain regions,” respectively. Therefore, the gate insulating film, the gate electrode, and the source/drain regions of the anti-fuse element of the present invention do not necessarily correspond to the gate insulating film, the gate electrode, and the source/drain regions of a typical MOS transistor in terms of functionality in circuit operation.

### Second Exemplary Embodiment

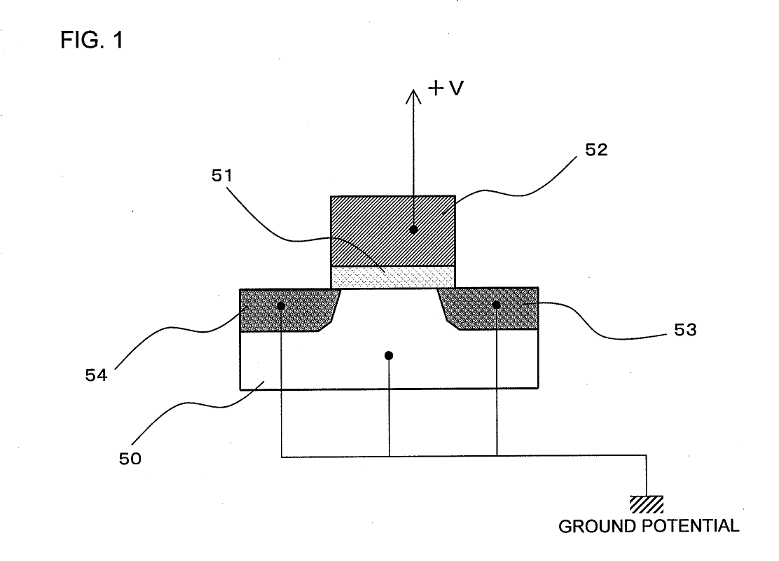

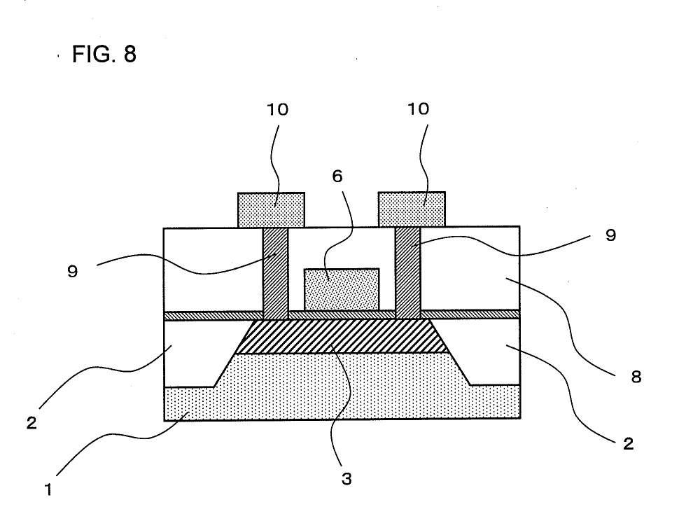

An anti-fuse element differently configured from the first exemplary embodiment will be described below. First, the incomplete anti-fuse element shown in FIG. 5, which was in the middle of the manufacturing process, was formed in accordance with the same manufacturing method as that described with reference to FIGS. 1 to 5 in the first exemplary embodiment. Interlayer insulating film 8 comprised of, for example, a silicon oxide film was then formed to cover first gate electrode 6, as shown in FIG. 8. Thereafter, tungsten or any other suitable material was used to form contact plugs 9 for connection with the first source/drain regions, a contact plug (not shown) for connection with the first gate electrode, and electrode-extending metal wired lines 10. A surface protecting insulating film was then formed, and an overlying metal wired line layer and other components were further formed as required. The anti-fuse element in the second exemplary embodiment was thus completed.

The second exemplary embodiment differs from the first exemplary embodiment in that the high-concentration impurity region and the first source/drain regions are formed in a single ion implantation process without ion implantation for newly forming first source/drain regions (corresponding to the portions 7 in FIG. 7) on both sides of first gate electrode 6. In the anti-fuse element of the second exemplary embodiment, high-concentration impurity region 3 and the first source/drain regions formed in the semiconductor substrate under the gate electrode have the same impurity concentration. The impurity concentration is approximately the same as that in first source/drain regions 7 formed in the first exemplary embodiment. Therefore, the resistance resulting from connection with contact plugs 9 and the electric resistance after forming the conduction paths will not increase even when first source/drain regions are not newly formed, whereby the anti-fuse element can operate without any problem.

In general, an anti-fuse element is formed and used along with other circuit elements formed based on MOS transistors or other components on the same semiconductor substrate in many cases. Therefore, in consideration of compatibility with the manufacturing methods for forming the other circuit elements, one may choose an optimum anti-fuse element from those of the first and second exemplary embodiments and combine it with the other circuit elements.

### Third Exemplary Embodiment

An anti-fuse element differently configured from the above exemplary embodiments will be described below. First, the incomplete anti-fuse element shown in FIG. 5, which was in the middle of the manufacturing process, was formed in accordance with the same manufacturing method as that described with reference to FIGS. 1 to 5 in the first exemplary embodiment.

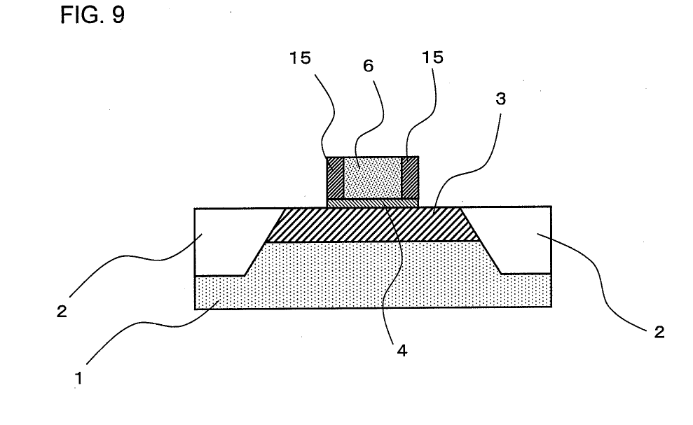

Thereafter, an insulating film comprised of, for example, a silicon nitride film (Si₃N₄) was formed to cover first gate electrode 6, and sidewall 15 comprised of the insulating film was formed on the side surface of the first gate electrode by performing anisotropic dry etching, as shown in FIG. 9.

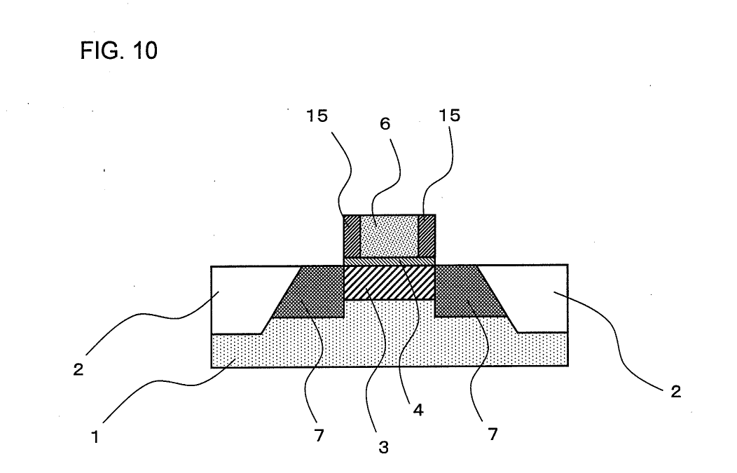

N-type impurity such as phosphorus and arsenic was then ion-implanted by using first gate electrode 6 and sidewall 15 as a mask to form first source/drain regions 7, as shown in FIG. 10. The ion implantation may be specifically carried out under the following conditions: the implantation energy ranges from 10 to 30 KeV, and the dosage ranges from approximately 1×10¹⁴ to 1×10¹⁶ atoms/cm². Thereafter, an interlayer insulating film, contact plugs, electrode-extending metal wired lines, and other components were formed, as in the first exemplary embodiment. The anti-fuse element in the third exemplary embodiment was thus completed.

The third exemplary embodiment differs from the first exemplary embodiment in that sidewall 15 was formed on the side surface of first gate electrode 6. When a MOS transistor is formed simultaneously with the anti-fuse element on the same semiconductor substrate, a sidewall is formed on a second gate electrode for the MOS transistor in many cases in consideration of reliability and other performance. Therefore, in consideration of compatibility with the method for manufacturing a MOS transistor, the anti-fuse element preferably includes a sidewall. In the third exemplary embodiment, the positions of first source/drain regions 7 at the ends of the gate electrode are shifted, because sidewall 15 is formed on the side surface of first gate electrode 6 of the anti-fuse element. In the anti-fuse element of the third exemplary invention, since high-concentration impurity region 3 that has been formed in advance under the first gate electrode, the anti-fuse element can be operated in a stable manner even when sidewall 15 is formed.

### Fourth Exemplary Embodiment

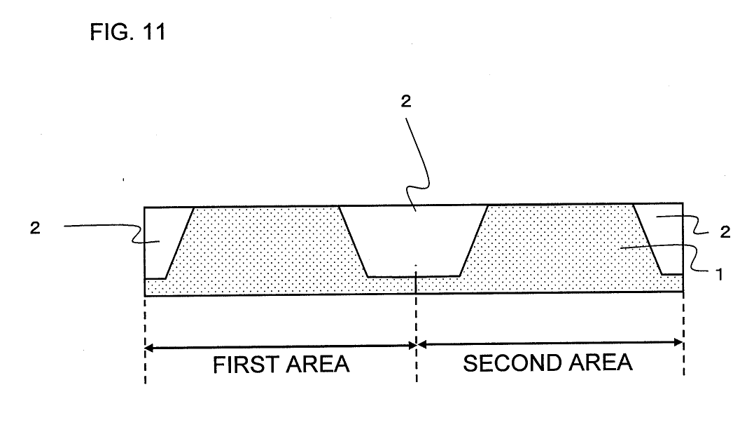

A semiconductor device with an anti-fuse and a MOS transistor formed on the same semiconductor chip will be described below. Isolation region 2 comprised of an insulating film was formed in semiconductor substrate 1 made of P-type silicon, as shown in FIG. 11. An anti-fuse element was formed in a first area in semiconductor substrate 1, and a desired MOS transistor-based circuit element was formed in a second area. A P-type well may be formed in advance in each of the first and second areas by introducing P-type impurity such as boron into semiconductor substrate 1 to a low concentration (approximately 1×10¹³ atoms/cm²) in an ion implantation process.

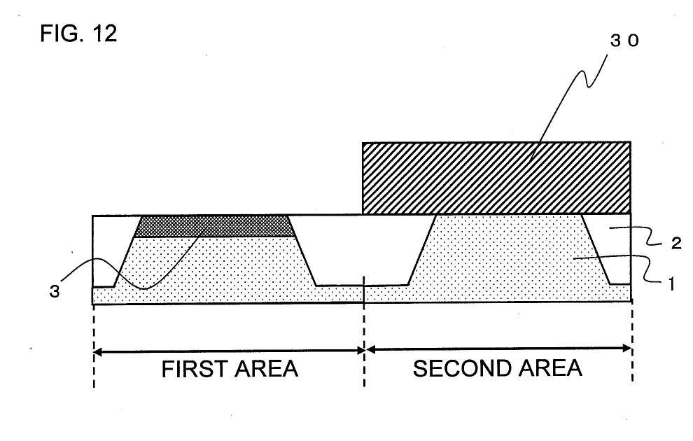

Photoresist film 30 was then used to form a mask pattern (corresponding to a first mask) to cover the second area in which a MOS transistor is to be formed, as shown in FIG. 12. Thereafter, phosphorus or arsenic (corresponding to a first impurity) was ion-implanted to form N-type high-concentration impurity region 3 only in the first area. The ion implantation can be carried out under the following conditions: the implantation energy ranges from 10 to 30 KeV, and the dosage ranges from approximately 1×10¹⁴ to 1×10¹⁶ atoms/cm². After the formation of high-concentration impurity region 3, photoresist film 30 was removed.

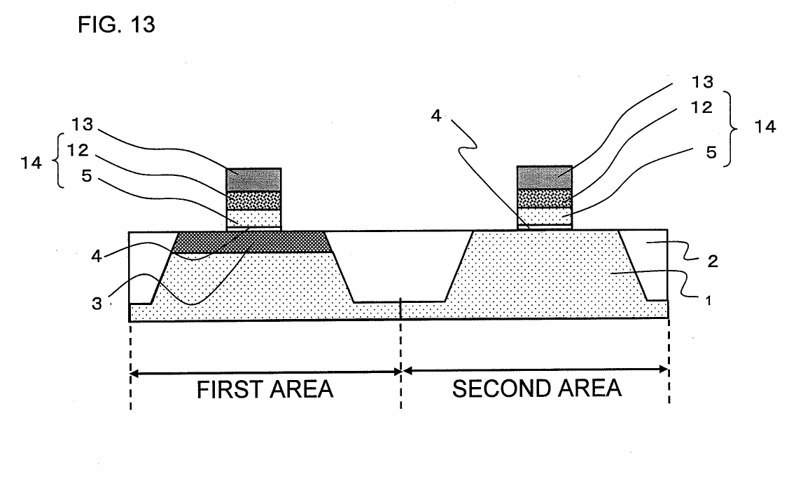

On semiconductor substrate 1 were then formed first and second gate insulating film 4 comprised of a silicon oxide film, polycrystalline silicon film 5 to which an impurity was introduced, high melting point metal film 12 made of tungsten, and silicon nitride film 13 as a surface protective film, as shown in FIG. 13. Thereafter, the resultant structure was patterned by using known photolithography and dry etching technologies to form first and second gate electrodes 14 and overlying silicon nitride films 13. Surface protective silicon nitride films 13 also served as a hard mask when first and second gate electrodes 14 were dry etched and patterned.

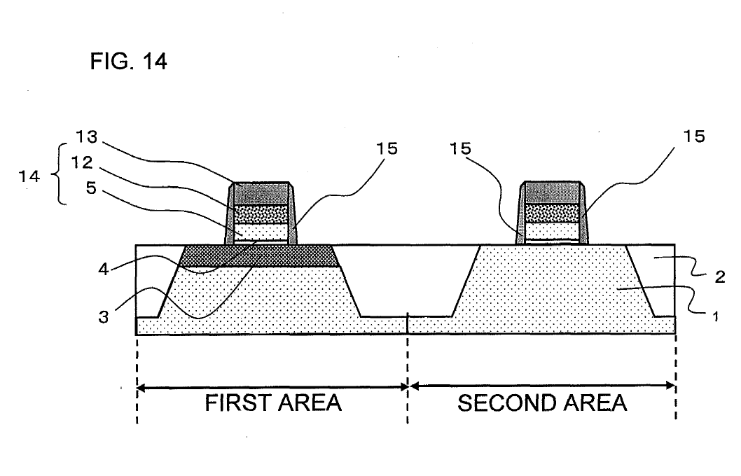

Thereafter, an insulating film comprised of, for example, a silicon nitride film was then formed to cover first and second gate electrodes 14, and sidewall 15 was formed on the side surface of each of first and second gate electrodes 14 in an anisotropic dry etching process, as shown in FIG. 14.

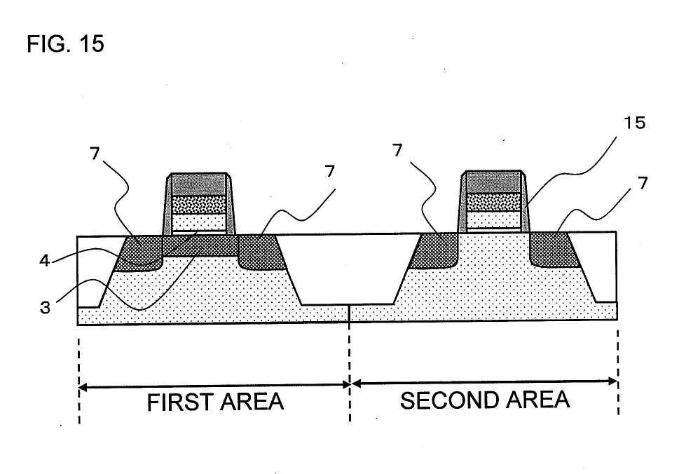

N-type impurity such as phosphorus and arsenic (corresponding to a second impurity) was then ion-implanted by using silicon nitride films 13 and sidewalls 15 as a mask to form first and second source/drain regions 7 in the first and second areas, respectively, as shown in FIG. 15. The ion implantation may be specifically carried out under the following conditions: the implantation energy ranges from 10 to 30 KeV, and the dosage ranges from approximately 1×10¹⁴ to 1×10¹⁶ atoms/cm².

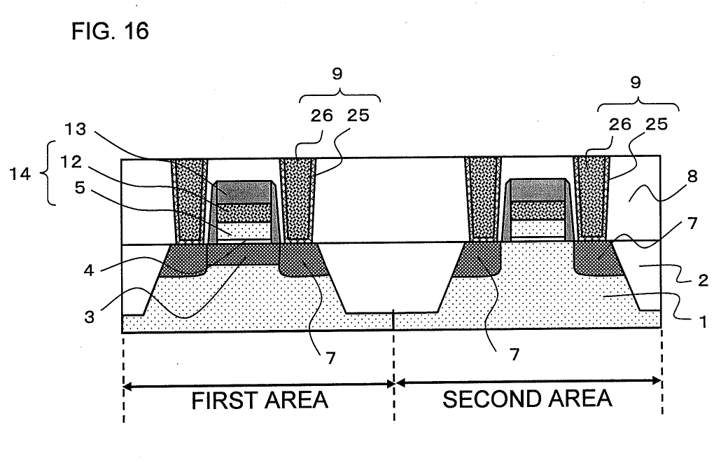

Interlayer insulating film 8 comprised of, for example, a silicon oxide film was then formed to cover first and second gate electrodes 14, as shown in FIG. 16. Thereafter, contact plugs 9 each of which including film 25 and tungsten 26 were formed, film 25 containing titanium (Ti) or any other suitable material that serves as a barrier metal. Although not shown, similar contact plugs connected to the first and second gate electrodes were formed. Electrode-extending metal wired lines, surface protective insulating films, and other components were then formed. The semiconductor device with the anti-fuse element and the MOS transistor formed on the same chip was thus completed.

In addition to the fourth exemplary embodiment, the present invention is applicable by modifying the structure of the anti-fuse element portion in accordance with the structure of the MOS transistor formed on the same semiconductor substrate to the extent that the anti-fuse element does not depart from the scope of the present invention. Further, to form a CMOS circuit element on the same semiconductor substrate, an N-type well may be formed in advance in the area in which the P-type MOS transistor is to be formed, and P-type impurity such as boron may be introduced to form the second source/drain regions.

An N-type well may be formed in advance also in the area in which the anti-fuse element is to be formed in accordance with the formation of the CMOS circuit element, and high-concentration impurity region 3 and first source/drain regions 7, which compose the anti-fuse element, may be formed from a P-type high-concentration diffusion layer.

### Fifth Exemplary Embodiment

A description will be made of a semiconductor device with an anti-fuse of the present invention and a MOS transistor formed on the same chip, in particular, a semiconductor device with an improved performance anti-fuse element.

First, the incomplete semiconductor device shown in FIG. 14, which is in the middle of the manufacturing process, was formed in accordance with the same manufacturing method as that described with reference to FIGS. 11 to 14 in the fourth exemplary embodiment. The ion implantation conditions in the formation of N-type high-concentration impurity region 3 were changed from those set and described in the fourth exemplary embodiment. Phosphorus (corresponding to a first impurity) can be ion-implanted under the following conditions: the implantation energy is 15 KeV and the dosage is 5×10¹⁶ atoms/cm².

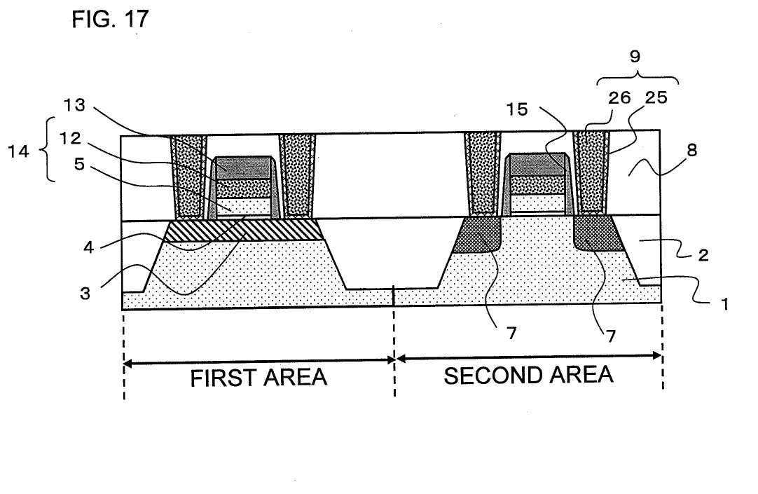

A second mask (not shown) comprised of a photoresist film was formed to cover the first area, and then an N-type impurity (corresponding to a third impurity) was ion-implanted to form second source/drain regions 7 only in the second area, as shown in FIG. 17. To form second source/drain regions 7, phosphorus can be ion-implanted under the following conditions: the implantation energy is 15 KeV and the dosage is 3×10¹⁵ atoms/cm². After the ion implantation, the photoresist film covering the first area was removed. Interlayer insulating film 8, contact plugs 9, electrode-extending metal wired lines, surface protective insulating films, and other components were then formed, as in the fourth exemplary embodiment. The semiconductor device with the anti-fuse element of the present invention and the MOS transistor formed on the same chip was thus completed.

In the fifth exemplary embodiment, the impurity concentration in high-concentration impurity region 3 of the anti-fuse element formed in the first area is higher than the impurity concentration in second source/drain regions 7 of the MOS transistor formed in the second area. When the impurity concentration in the second source/drain regions for the MOS transistor is higher than necessary, the operation characteristics, reliability, and other performance of the transistor are degraded. In the semiconductor device of the fifth exemplary embodiment, however, the impurity concentration in the second source/drain regions for the MOS transistor can be set irrespective of that in high-concentration impurity region 3 of the anti-fuse element. The anti-fuse element and the MOS transistor formed on the same semiconductor substrate can therefore be readily optimized in accordance with desired respective operation characteristics. Further, in the fifth exemplary embodiment, the MOS transistor may be N-type or P-type. In the fifth exemplary embodiment, since the ion implantation for the MOS transistor is carried out separately from that for the anti-fuse element, the MOS transistor can be set to a desired conduction type, either N-type or P-type, irrespective of the conduction type of the anti-fuse element.

When conduction type of the first gate electrode of the anti-fuse element is set to a same conduction type of both the high-concentration impurity region and the first source/drain regions of the anti-fuse element, the anti-fuse element can operate in a more stable manner. In this case, a resistivity of the conduction path of the anti-fuse element in conduction state is lower.

The values used in the ion implantation shown in the exemplary embodiments are presented by way of example, and can be changed in accordance with desired characteristics of a semiconductor device to be manufactured.

It is apparent that the present invention is not limited to the above embodiments, but may be modified and changed without departing from the scope and spirit of the invention.

What is claimed is:

1. A semiconductor device comprising an anti-fuse element, the anti-fuse element including:
a semiconductor substrate;
a first gate insulating film and a first gate electrode sequentially formed on the semiconductor substrate;
a high-concentration impurity region formed in the semiconductor substrate under the first gate electrode; and
first source/drain regions formed in the semiconductor substrate on both sides of the high-concentration impurity region, the first source/drain regions containing an impurity having the same conduction type as conduction type of the high-concentration impurity region.

2. The semiconductor device according to claim 1,
wherein the high-concentration impurity region comprises the impurity having impurity concentration different from impurity concentration in the first source/drain regions.

3. The semiconductor device according to claim 1,
wherein the anti-fuse element further includes sidewalls on both sides of the first gate electrode, and
the high-concentration impurity region is located in the semiconductor substrate under the first gate electrode and the sidewalls.

4. The semiconductor device according to claim 1, further comprising a planar transistor including:
a second gate insulating film and a second gate electrode sequentially formed on the semiconductor substrate; and
second source/drain regions formed in the semiconductor substrate on both sides of the second gate electrode.

5. The semiconductor device according to claim 4,
wherein the planar transistor further includes sidewalls on both sides of the second gate electrode, and
the second source/drain regions are formed in the semiconductor substrate on both sides of the second gate electrode and the sidewalls.

6. The semiconductor device according to claim 4,
wherein impurity concentration of the high-concentration impurity region is larger than impurity concentration of the second source/drain regions.

7. The semiconductor device according to claim 4,
wherein conduction type of the first gate electrode is different from conduction type of the second gate electrode.

8. The semiconductor device according to claim 4,
wherein conduction type of the first gate electrode, the high-concentration impurity region and the first source/drain regions are same.

9. The semiconductor device according to claim 8,
wherein conduction type of the second source/drain regions is different from conduction type of the first source/drain regions.

10. A method for manufacturing a semiconductor device including an anti-fuse element, the method comprising:
implanting an impurity into a predetermined area of a semiconductor substrate to form a high-concentration impurity region and first source/drain regions in the semiconductor substrate on both sides of the high-concentration impurity region; and
sequentially forming a first gate insulating film and a first gate electrode on the high-concentration impurity region to form the anti-fuse element.

11. The method for manufacturing a semiconductor device according to claim 10, further comprising:
forming a first mask on a semiconductor area other than the predetermined area of the semiconductor substrate, before implanting the impurity into the predetermined area of the semiconductor substrate;
removing the first mask, after implanting the impurity into the predetermined area of the semiconductor substrate;
forming a second gate insulating film and a second gate electrode on the semiconductor area, simultaneously with the formation of the first gate insulating film and the first gate electrode;
forming a second mask on the anti-fuse element, after forming the first gate insulating film and the first gate electrode;
implanting a third impurity into the semiconductor area on both sides of the second gate electrode by using the second mask as a mask, to form second source/drain regions and then obtain a planar transistor; and
removing the second mask.

12. The method for manufacturing a semiconductor device according to claim 11,
wherein in forming the first gate insulating film and the first gate electrode, sidewalls are further formed on both sides of the first gate electrode,
in forming the second gate insulating film and the second gate electrode, sidewalls are further formed on both sides of the second gate electrode, and
in implanting the third impurity into the semiconductor area, the third impurity is implanted into the semiconductor area on both sides of the second gate electrode and the sidewalls, to form the second source/drain regions.

13. A method for manufacturing a semiconductor device including an anti-fuse element, the method comprising:
implanting a first impurity into a predetermined area of a semiconductor substrate;
sequentially forming a first gate insulating film and a first gate electrode on part of the predetermined area, to define the predetermined area under the first gate electrode as a high-concentration impurity region comprising the first impurity; and
implanting a second impurity having the same conduction type as conduction type of the first impurity into the predetermined area on both sides of the first gate electrode, to form first source/drain regions, and then obtain the anti-fuse element.

14. The method for manufacturing a semiconductor device according to claim 13, further comprising:
forming a first mask on a semiconductor area other than the predetermined area of the semiconductor substrate, before implanting the first impurity into the predetermined area of the semiconductor substrate;
removing the first mask, after implanting the first impurity into the predetermined area of the semiconductor substrate;
forming a second gate insulating film and a second gate electrode on the semiconductor area, simultaneously with the formation of the first gate insulating film and the first gate electrode; and
implanting the second impurity into the semiconductor area on both sides of the second gate electrode, to form second source/drain regions, simultaneously with implantation of the second impurity into the predetermined area.

15. The method for manufacturing a semiconductor device according to claim 14,
wherein in forming the first gate insulating film and the first gate electrode, sidewalls are further formed on both sides of the first gate electrode,
in implanting the second impurity to form the first source/drain regions, the second impurity is implanted into the predetermined area on both sides of the first gate electrode and the sidewalls, to form the first source/drain regions,
in forming the second gate insulating film and the second gate electrode, sidewalls are further formed on both sides of the second gate electrode, and
in implanting the second impurity to form the second source/drain regions, the second impurity is implanted into the semiconductor area on both sides of the second gate electrode and the sidewalls, to form the second source/drain regions.
